(19) United States
(12) Patent Application Publication
(10) Pub. No.: US 2015/0124413 A1
(43) Pub. Date: May 7, 2015

(54) DISPLAY UNIT AND ELECTRONIC APPARATUS

(71) Applicant: Sony Corporation, Tokyo (JP)

(72) Inventors: Masato Suzuki, Kanagawa (JP); Shota Nishi, Kanagawa (JP)

(21) Appl. No.: 14/408,146

(22) PCT Filed: Jul. 3, 2013
(86) PCT No.: PCT/JP2013/004125

§ 371 Date: Dec. 15, 2014

(30) Foreign Application Priority Data
Jul. 9, 2012 (JP) 2012-153301

(51) Int. Cl. G02B 1/16; H05K 7/02; G02F 1/167

(52) U.S. Cl. CPC G02B 1/16; G02F 1/167; H05K 7/02
USPC 361/748

(57) ABSTRACT

A display unit includes: a display section displaying an image; a base film having a first surface provided with a drive circuit, the drive circuit controlling the display section; and a sheet antistatic-finished and bonded to a second surface opposite to the first surface of the base film, in which the sheet is larger in size than the base film.

### TECHNICAL FIELD

The present disclosure relates to a display unit and an electronic apparatus. More specifically, the present disclosure relates to a display unit and an electronic apparatus which prevent a base film from being electrostatically charged through bonding, to the base film, an antistatic-finished sheet larger in size than the base film, thereby suppressing an influence of electrostatic charge on a drive circuit and improving handleability.

### BACKGROUND ART

Examples of electronic apparatuses include various kinds including display units such as tablet devices with an electronic book reader function and television receivers, mobile devices typified by cellular phones, recording-reproducing apparatuses such as disk recording-reproducing apparatuses, and image pickup apparatuses such as still cameras and video cameras.

In these electronic apparatuses, a drive circuit for driving a predetermined section is typically included. For example, a drive circuit for driving a display is provided to a display unit. Examples of the display included in the display unit include a flat panel display using thin film transistors (TFTs).

In some of the above-described electronic apparatuses, a drive circuit is formed on a base film. For example, in the flat panel display, a drive circuit performing a drive to display an image is formed on a base film.

In a display unit including a flat panel display, a base film and the like are formed by a roll-to-roll flow method, a bonding flow method to a supporting substrate, a direct flow method such as spin coating, a thin film formation method by coating over a supporting substrate, or the like.

A display unit is manufactured as follows. Electronic components and the like are mounted on the base film formed by any of the above-described methods to form a drive circuit, and a connection substrate is bonded to the drive circuit, and then a display section such as a flat panel display is mounted (refer to PTL 1).

In a technique in PTL 1, there is described an example in which a thin film device such as a display is manufactured through forming a base film and a drive circuit on a substrate (a manufacturing base substrate), and peeling the substrate in a final step.

### CITATION LIST

### Patent Literature

[PTL 1]

Japanese Unexamined Patent Application Publication No. 2007-88235

### SUMMARY

### Technical Problem

When a base film on which a drive circuit is formed is electrostatically charged, the drive circuit may be affected, and the operation of the drive circuit may be hampered.

However, in an electronic apparatus (a display unit) described in PTL 1, countermeasures against static electricity are not taken for the base film, and electrostatic charge may affect the operation of the drive circuit accordingly.

Moreover, in a process of manufacturing the electronic apparatus, it is necessary to consider handleability such as product handling ability. For example, if favorable handling ability is not secured in transportation of the base film or the like by a robot or the like or assembling of the base film or the like into another component, the base film or the drive circuit may be damaged.

It is desirable to suppress an influence on a drive circuit and to improve handleability in a display unit and an electronic apparatus.

### Solution to Problem

According to an embodiment of the present disclosure, there is provided a display unit including: a display section displaying an image; a base film having a first surface provided with a drive circuit, the drive circuit controlling the display section; and a sheet antistatic-finished and bonded to a second surface opposite to the first surface of the base film, in which the sheet is larger in size than the base film.

Therefore, in the display unit, an outer peripheral portion of the antistatic-finished sheet is located outside an outer periphery of the base film.

In the above-describe display unit, it is desirable that a portion projected from the base film of the sheet be provided as a projection section, a reinforcing member be attached to the projection section, and a connection substrate be bonded to the reinforcing member to be connected to the drive circuit.

When the portion projected from the base film of the sheet is provided as a projection section, the reinforcing member is attached to the projection section, and the connection substrate is bonded to the reinforcing member to be connected to the drive circuit, strength of the connection substrate is improved.

In the above-described display unit, it is desirable that the drive circuit be formed on the base film on a supporting substrate supporting the base film, and the sheet be bonded to the base film peeled from the supporting substrate.

When the drive circuit is formed on the base film on the supporting substrate supporting the base film, and the sheet is bonded to the base film peeled from the supporting substrate, the sheet allows the base film and the drive circuit to secure a certain level of stiffness.

In the above-described display unit, it is desirable that the sheet be bonded to the base film with an adhesive, and the adhesive contain a conductive material.

When the sheet is bonded to the base film with the adhesive, and the adhesive contains a conductive material, static electricity is discharged into the air.

In the above-described display unit, it is desirable that a surface opposite to a surface bonded to the base film of the sheet be subjected to surface roughening.

When the surface opposite to the surface bonded to the base film of the sheet is subjected to surface roughening, the sheet is less likely to be electrostatically charged.

In the above-described display unit, it is desirable that the sheet be formed of a metal material.

When the sheet is formed of a metal material, hardness and thermal conductivity of the sheet are enhanced.

In the above-described display unit, it is desirable that the sheet be formed of a resin material.

When the sheet is formed of a resin material, the weight of the sheet is reduced.

In the above-described display unit, it is desirable that the sheet contain a conductive material.

When the sheet contains a conductive material, it is not necessary to form a conductive material on the sheet by coating.

According to an embodiment of the present disclosure, there is provided an electronic apparatus including: a base film having a first surface provided with a drive circuit; and a sheet antistatic-finished and bonded to a second surface opposite to the first surface of the base film, in which the sheet is larger in size than the base film.

Therefore, in the electronic apparatus, an outer peripheral portion of the antistatic-finished sheet is located outside an outer periphery of the base film.

### Advantageous Effects of Invention

The display unit according to the embodiment of the disclosure includes: a display section displaying an image; a base film having a first surface provided with a drive circuit, the drive circuit controlling the display section; and a sheet antistatic-finished and bonded to a second surface opposite to the first surface of the base film, in which the sheet is larger in size than the base film.

Therefore, the sheet is antistatic-finished, and the projection section is allowed to be used as a handling section or the like, for example, in transportation of the base substrate or the like by a robot or the like or assembling of the base substrate or the like into another component. Accordingly, an influence on the drive circuit is allowed to be suppressed, and handleability is improvable.

In the display unit, a portion projected from the base film of the sheet may be provided as a projection section, a reinforcing member may be attached to the projection section, and a connection substrate may be bonded to the reinforcing member to be connected to the drive circuit.

Therefore, the connection substrate is allowed to be easily connected to the drive circuit, and an improvement in workability is achievable.

In the display unit, the drive circuit may be formed on the base film on a supporting substrate supporting the base film, and the sheet may be bonded to the base film peeled from the supporting substrate.

Therefore, the drive circuit is allowed to be formed onto the base film on the supporting substrate, and effective workability in formation of the drive circuit is achievable.

In the display unit, the sheet may be bonded to the base film with an adhesive, and the adhesive may contain a conductive material.

Therefore, electrostatic charge on the sheet is allowed to be suppressed, thereby suppressing an influence of the electrostatic charge on the drive circuit.

In the display unit, a surface opposite to a surface bonded to the base film of the sheet may be subjected to surface roughening.

Therefore, the sheet is less likely to be electrostatically charged, and the influence of electrostatic charge on the drive circuit is allowed to be suppressed.

In the display unit, the sheet may be formed of a metal material.

Therefore, stiffness of the sheet is allowed to be enhanced to improve strength of the sheet, and thermal conductivity of the sheet is allowed to be enhanced to secure high thermal dissipation.

In the display unit, the sheet may be formed of a resin material.

Therefore, a reduction in weight of the sheet is achievable, and a reduction in manufacturing cost is achievable.

In the display unit, the sheet may contain a conductive material.

Therefore, electrostatic charge on the sheet is allowed to be suppressed effectively, thereby reliably suppressing the influence of electrostatic charge on the drive circuit.

The electronic apparatus according to the embodiment of the present disclosure includes: a base film having a first surface provided with a drive circuit; and a sheet antistatic-finished and bonded to a second surface opposite to the first surface of the base film, in which the sheet is larger in size than the base film.

Therefore, the sheet is antistatic-finished, and the projection section is allowed to be used as a handling section or the like in transportation of the base substrate or the like by a robot or the like or assembling of the base substrate or the like into another component. Accordingly, an influence on the drive circuit is allowed to be suppressed, and handleability is improvable.

It is to be understood that both the foregoing general description and the following detailed description are exemplary, and are intended to provide further explanation of the technology as claimed.

### BRIEF DESCRIPTION OF DRAWINGS

FIG. 1 illustrates, along with FIGS. 2 to 7, a display unit and an electronic apparatus according to an embodiment of the present disclosure, and FIG. 1 is a schematic perspective view of the display unit.

FIG. 2 is a schematic perspective view illustrating a base substrate, a display section, and a sheet.

FIG. 3 illustrates, along with FIGS. 4 to 7, states in a process of manufacturing the base substrate and the like, and FIG. 3 is a schematic enlarged sectional view illustrating a state in which a base film is formed on a supporting substrate.

FIG. 4 is a schematic enlarged sectional view illustrating a state in which a drive circuit is formed on the base film.

FIG. 5 is a schematic enlarged sectional view illustrating a state in which the base film is peeled from the supporting substrate.

FIG. 6 is a schematic enlarged sectional view illustrating a state in which the sheet is bonded to the base film.

FIG. 7 is a schematic enlarged sectional view illustrating a state in which a reinforcing member is attached to the sheet, and a connection substrate is bonded to the reinforcing member and the drive circuit.

### DESCRIPTION OF EMBODIMENTS

Some embodiments of the present disclosure will be described in detail below referring to the accompanying drawings.

A display unit and an electronic apparatus according to an embodiment described hereinafter of the present disclosure is applied to a tablet device. It is to be noted that an application range of the embodiment of the present disclosure is not limited to the tablet device, and the embodiment of the present disclosure may be widely applicable to various apparatuses and devices functioning as a display unit or an electronic apparatus. The various apparatuses and devices include television receivers, monitors, personal computers, cellular phones, image pickup apparatuses such as video cameras and still cameras, recording-reproducing apparatuses, audio equipment, and the like.

As used herein, terms “front”, “rear”, “top”, “bottom”, “right” and “left” refer to directions viewed from a display surface of the tablet device. Accordingly, a user's side is defined as a front side, and a side opposite to the user's side is defined as a rear side.

It is to be noted that the terms “front”, “rear”, “top”, “bottom”, “right”, and “left” used herein are defined for convenience of description, and the embodiments of the present disclosure are not limited to these directions.

### (Schematic Configurations of Electronic Apparatus and Display Unit)

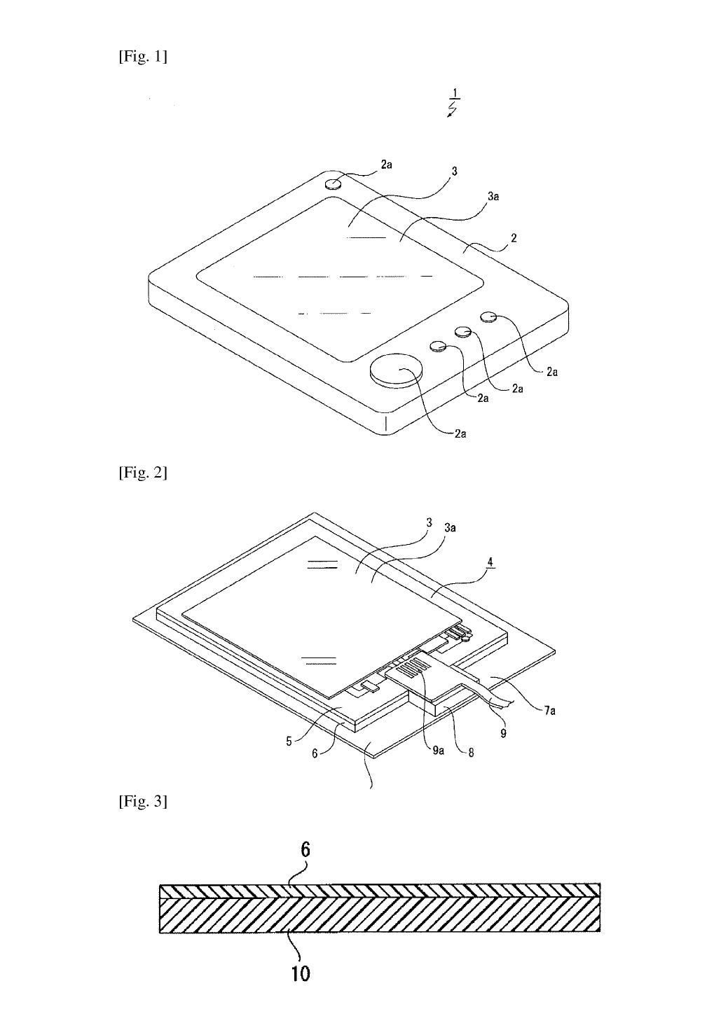

A schematic configuration of a display unit also functioning as an electronic apparatus will be described below (refer to FIG. 1).

A display unit 1 is, for example, a tablet device such as an electronic book reader. The display unit 1 includes a thin enclosure 2 and a display section 3 held in the enclosure 2.

Necessary components are disposed in and on the enclosure 2. Various kinds of operation sections 2a are disposed on an external surface of the enclosure 2. Examples of the operation sections 2a include a power button, a mode switch key, and a volume key. When the operation sections 2a are operated, various operations such as an on-off operation of a power supply, a mode switching operation, and a screen displaying operation and a screen switching operation of the display section 3 are performed.

An opening is formed in a front surface of the enclosure 2, and the display section 3 located corresponding to the opening is disposed in the opening.

The display section 3 is, for example, an electrophoretic display, and a front surface of the display section 3 is formed as a display surface 3a.

### (Specific Configuration of Display Unit)

Next, a specific configuration of the display unit 1 will be described below (refer to FIG. 2).

A base substrate 4 is disposed inside the display unit 1.

The base substrate 4 includes a drive circuit 5, a base film 6, and a sheet 7 arranged in this order from the front side.

The display section 3 is disposed on a front surface of the drive circuit 5, and the drive circuit 5 performs various kinds of control, on the display section 3, such as screen displaying and screen switching. An electrode section (not illustrated) is provided to a bottom portion of the front surface of the drive circuit 5.

The base film 6 serves as a base section for forming the drive circuit 5. The base film 6 may be formed of, for example, a resin material.

The sheet 7 is bonded to the base film 6 with an adhesive. The adhesive contains, for example, a conductive material. When the adhesive contains the conductive material, static electricity is discharged into the air, and electrostatic charge on the sheet 7 is allowed to be suppressed, thereby suppressing an influence of electrostatic charge on the drive circuit 5.

Moreover, the sheet 7 is antistatic-finished. When the sheet 7 is antistatic-finished, electrostatic charge on the sheet 7 is allowed to be suppressed, thereby suppressing the influence of electrostatic charge on the drive circuit 5.

Further, when the adhesive contains a conductive material, and the sheet 7 is antistatic-finished, an antistatic effect is enhanced; therefore, a further reduction in the influence of electrostatic charge on the drive circuit 5 is achievable.

The sheet 7 may be formed of, for example, a resin material. Examples of the resin material used for the sheet 7 include polyethylene terephthalate, polycarbonate, polyimide, polyether sulfone, polyethylene naphthalate, polyethylene, polypropylene, and polytetrafluoroethylene. When the sheet 7 is formed of the resin material, a weight reduction is achievable, and a reduction in manufacturing cost is also achievable.

Further, the sheet 7 may be formed of a metal material. As the metal material, aluminum, titanium, stainless steel, or the like is used. When the sheet 7 is formed of the metal material, stiffness is allowed to be enhanced, and thermal conductivity is allowed to be enhanced to secure high thermal dissipation.

The sheet 7 is larger in size than the base film 6, and an outer peripheral portion of the sheet 7 is located outside an outer periphery of the base film 6. The outer peripheral portion located outside the outer periphery of the base film 6 in the sheet 7 is provided as a projection section 7a.

Thus, the sheet 7 is larger in size than the base film 6, and includes the projection section 7a; therefore, the projection section 7a is allowed to be used as a handling section in transportation of the base substrate 4 or the like by a robot or the like or assembling of the base substrate 4 or the like into another component. Therefore, a favorable ability of handling the base substrate 4 or the like is allowed to be secured, and damage to the base film 6 or the drive circuit 5 is preventable.

Moreover, the projection section 7a may be used as a clamp portion serving as a ground during grounding. Further, the projection section 7a may be also used as a portion where a character or a symbol such as a lot number is written.

It is to be noted that when the sheet 7 is formed of the resin material, the sheet 7 may contain a conductive material.

Typically, when a conductive material is formed on the sheet 7 by coating, the conductive material may be peeled from the sheet 7. When the conductive material is peeled from the sheet 7, the antistatic effect is reduced.

Therefore, when the sheet 7 contains the conductive material in the above-described manner, peeling of the conductive material does not occur; therefore, electrostatic charge on the sheet 7 is allowed to be effectively suppressed, thereby reliably suppressing the influence of electrostatic charge on the drive circuit 5.

A reinforcing member 8 is attached to the projection section 7a of the sheet 7, and a connection substrate 9 is bonded onto the reinforcing member 8 with an adhesive. As the connection substrate 9, for example, a flexible printed circuit board is used. A terminal section 9a of the connection substrate 9 is connected to the electrode section of the drive circuit 5 by, for example, thermocompression bonding. The reinforcing member 8 also serves as a spacer for aligning the connection substrate 9 with the drive circuit 5.

When the connection substrate 9 is connected to the drive circuit 5 through the reinforcing member 8 functioning as a spacer in such a manner, the connection substrate 9 is allowed to be easily connected to the drive circuit 5, and an improvement in workability is achievable. In addition, when the connection substrate 9 is bonded to the reinforcing member 8, a bonding area of the connection substrate 9 is increased, and an improvement in strength of the connection substrate 9 and stabilization of a connection state of the connection substrate 9 with the drive circuit 5 are achievable.

It is to be noted that a rear surface of the sheet 7 may be subjected to surface roughening. Thus, the sheet 7 is less likely to be electrostatically charged, and the influence of electrostatic charge on the drive circuit 5 is allowed to be suppressed.

### (Process of Manufacturing Base Substrate and the Like)

A process of manufacturing the base substrate 4 and the like will be described below (refer to FIGS. 3 to 7).

The base substrate 4 includes the drive circuit 5, the base film 6, and the sheet 7, as described above.

In manufacturing of the base substrate 4, first, the base film 6 is formed, and a supporting substrate 10 is used to form the base film 6 (refer to FIG. 3).

The supporting substrate 10 has a flat plate shape, and, for example, a material with high hardness such as glass is used for the supporting substrate 10. When the material with high hardness is used for the supporting substrate 10, the base film 6 is easily formed on the supporting substrate 10.

The base film 6 is formed on the supporting substrate 10 by coating of a coating material. The supporting substrate 10 is coated by, for example, a spin coating method or a slit coating method.

Next, the drive circuit 5 is formed on the base film 6 by a photolithography process (refer to FIG. 4). As described above, since the material with high hardness is used for the supporting substrate 10, the drive circuit 5 is easily formed on the base film 6.

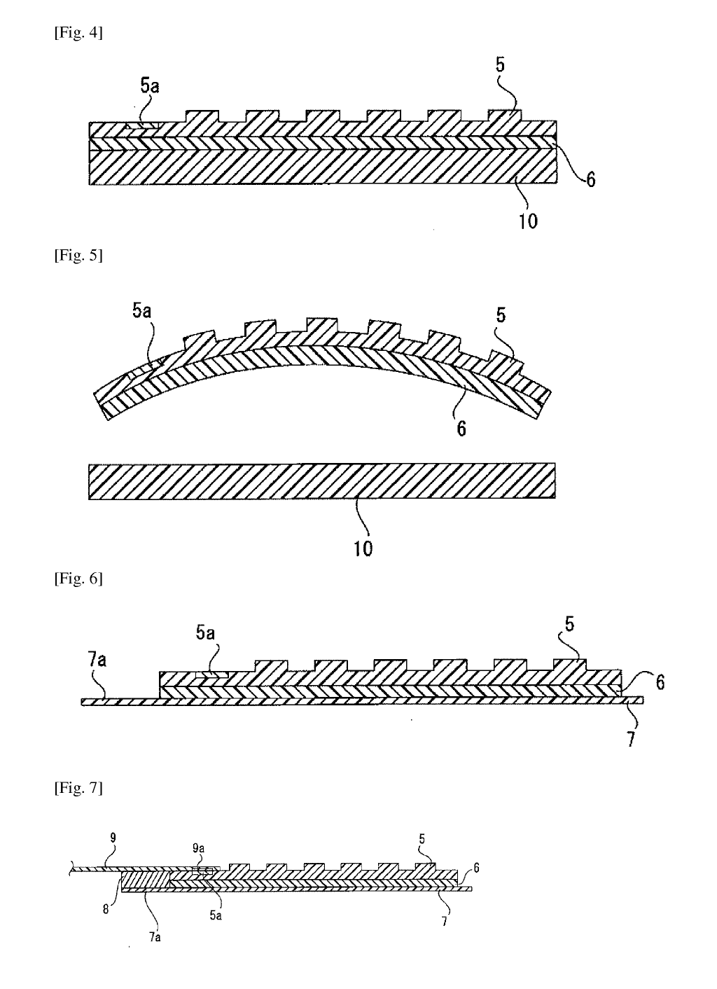

Next, the base film 6 on which the drive circuit 5 is formed is peeled from the supporting substrate 10 (refer to FIG. 5). Since the base film 6 and the drive circuit 5 have high flexibility, it is necessary for the base film 6 and the drive circuit 5 to secure a certain level of stiffness in a state in which they are peeled from the supporting substrate 10.

Then, the antistatic-finished sheet 7 is bonded to a surface opposite to the surface where the drive circuit 5 is formed of the peeled base film 6 with an adhesive (refer to FIG. 6). Accordingly, the base film 6 and the drive circuit 5 secure a certain level of stiffness, and strengths of the base film 6 and the sheet 7 are improvable.

Next, the reinforcing member 8 is attached to the projection section 7a of the sheet 7 (refer to FIG. 7). Then, the connection substrate 9 is bonded to the reinforcing member 8 serving as a spacer and the drive circuit 5 with an adhesive, and an electrode section 9a of the connection substrate 9 is bonded to an electrode section 5a of the drive circuit 5 by, for example, thermocompression bonding.

As described above, in the display unit 1, the sheet 7, which is antistatic-finished in the above-described manufacturing process, is bonded to the base film 6. Therefore, the influence of electrostatic charge on the drive circuit 5 is allowed to be suppressed during the manufacturing process.

Moreover, the sheet 7 is still bonded to the base film 6 even after shipment of the display unit 1 as a product. Therefore, the influence of electrostatic charge on the drive circuit 5 is allowed to be suppressed during transportation of the display unit 1 or during use of the display unit 1 as a product.

### Summary

As described above, in the display unit 1, the antistatic-finished sheet 7 is larger in size than the base film 6.

Therefore, when the sheet 7 is antistatic-finished, the influence of electrostatic charge on the drive circuit 5 is allowed to be suppressed, and the projection section 7a is allowed to be used as a handling section, thereby improving handleability.

### (Technology)

It is to be noted that the technology of the present disclosure is allowed to have the following configurations.
(1) A display unit including:
a display section displaying an image;
a base film having a first surface provided with a drive circuit, the drive circuit controlling the display section; and
a sheet antistatic-finished and bonded to a second surface opposite to the first surface of the base film,
in which the sheet is larger in size than the base film.
(2) The display unit according to (1), in which
a portion projected from the base film of the sheet is provided as a projection section,
a reinforcing member is attached to the projection section, and
a connection substrate is bonded to the reinforcing member to be connected to the drive circuit.
(3) The display unit according to (1) or (2), in which
the drive circuit is formed on the base film on a supporting substrate supporting the base film, and
the sheet is bonded to the base film peeled from the supporting substrate.
(4) The display unit according to any one of (1) to (3), in which
the sheet is bonded to the base film with an adhesive, and
the adhesive contains a conductive material.
(5) The display unit according to any one of (1) to (4), in which a surface opposite to a surface bonded to the base film of the sheet is subjected to surface roughening.
(6) The display unit according to any one of (1) to (5), in which the sheet is formed of a metal material.
(7) The display unit according to any one of (1) to (5), in which the sheet is formed of a resin material.
(8) The display unit according to (7), in which the sheet contains a conductive material.
(9) An electronic apparatus including:
a base film having a first surface provided with a drive circuit; and
a sheet antistatic-finished and bonded to a second surface opposite to the first surface of the base film,
in which the sheet is larger in size than the base film.

The specific shapes and configurations of the components described in the above-described embodiments of the present disclosure are merely examples for implementing the present disclosure and the technical range of the present disclosure should not be construed as being limited thereto.

The present disclosure contains subject matter related to that disclosed in Japanese Priority Patent Application No. 2012-153301 filed in the Japan Patent Office on Jul. 9, 2012, the entire content of which is hereby incorporated by reference.

It should be understood by those skilled in the art that various modifications, combinations, sub-combinations, and alterations may occur depending on design requirements and other factors insofar as they are within the scope of the appended claims or the equivalents thereof.

### REFERENCES SIGNS LIST

1 display unit
3 display section
5 drive circuit
6 base film
7 sheet
7a projection section
8 reinforcing member
9 connection substrate
10 supporting substrate

1. A display unit comprising:
a display section displaying an image;
a base film having a first surface provided with a drive circuit, the drive circuit controlling the display section; and
a sheet antistatic-finished and bonded to a second surface opposite to the first surface of the base film,
wherein the sheet is larger in size than the base film.

2. The display unit according to claim 1, wherein
a portion projected from the base film of the sheet is provided as a projection section,
a reinforcing member is attached to the projection section, and
a connection substrate is bonded to the reinforcing member to be connected to the drive circuit.

3. The display unit according to claim 1, wherein
the drive circuit is formed on the base film on a supporting substrate supporting the base film, and
the sheet is bonded to the base film peeled from the supporting substrate.

4. The display unit according to claim 1, wherein
the sheet is bonded to the base film with an adhesive, and
the adhesive contains a conductive material.

5. The display unit according to claim 1, wherein a surface opposite to a surface bonded to the base film of the sheet is subjected to surface roughening.

6. The display unit according to claim 1, wherein the sheet is formed of a metal material.

7. The display unit according to claim 1, wherein the sheet is formed of a resin material.

8. The display unit according to claim 7, wherein the sheet contains a conductive material.

9. An electronic apparatus comprising:
a base film having a first surface provided with a drive circuit; and
a sheet antistatic-finished and bonded to a second surface opposite to the first surface of the base film,
wherein the sheet is larger in size than the base film.
